(19) United States
(12) Patent Application Publication
(10) Pub. No.: US 2011/0294073 A1
(43) Pub. Date: Dec. 1, 2011

(54) PREPARING METHOD OF METAL POWDER AND METHOD OF MANUFACTURING INNER ELECTRODE OF MULTILAYER CERAMIC CAPACITOR USING THE SAME

(75) Inventors: Ji Hwan SHIN, Gyeonggi-do (KR); Sung Kwon Wi, Seoul (KR); Jun Hee Kim, Gyeonggi-do (KR)

(73) Assignee: SAMSUNG ELECTRO-MECHANICS CO., LTD.

(21) Appl. No.: 12/879,409

(22) Filed: Sep. 10, 2010

(30) Foreign Application Priority Data
May 28, 2010 (KR) 10-2010-0050215

(51) Int. Cl. G03F 7/20; B29C 59/02

(52) U.S. Cl. 430/319; 430/322; 264/293; 977/887

(57) ABSTRACT

The present invention provides a method for preparing metal powder, which includes the steps of: providing a base substrate; forming a pattern layer, having a concave-convex pattern of a predetermined shape, on the base substrate; forming a metal film separated from the pattern layer by the concave-convex pattern; and separating the metal film from the pattern layer, thereby naturally patterning the metal film in the predetermined shape, and a method for manufacturing inner electrodes of a multilayer ceramic capacitor using the same.

### CROSS-REFERENCE TO RELATED APPLICATIONS

This application claims the benefit of Korean Patent Application No. 10-2010-0050215 filed with the Korea Intellectual Property Office on May 28, 2010, the disclosure of which is incorporated herein by reference.

### BACKGROUND OF THE INVENTION

1. Field of the Invention

The present invention relates to metal powder; and, more particularly, to a method for preparing metal powder to have the shape and size desired by a worker and a method for manufacturing inner electrodes for a multilayer ceramic capacitor using the same.

2. Description of the Related Art

As electronic products have been recently developed to provide multiple and complex functions, electronic parts therein become smaller and thinner as well.

In most cases, conductive metal materials are used in manufacturing such electronic parts. The electronic parts include a number of circuits constituted by the conductive metal materials. In this case, the circuits play a role of current paths in the electronic parts. As described above, in line with miniaturization and thinness of the electronic parts, metal powders being raw materials of the parts have been rapidly micronized as well.

One example of this includes a multilayer ceramic capacitor considered as most important parts within electronic parts. In recent years, the multilayer ceramic capacitor has been developed toward miniaturization, thinness, and large-capacitance. In order to increase the capacitance of chip-products with a predetermined thickness, materials of dielectric ceramics should be adjusted with high permittivity. Alternatively, dielectric and electrode layer made of the same material as that of dielectric ceramics should be adjusted to have a low thickness so that the number of layers is increased within the same ship-products. At present, the thickness of ceramic green sheet has been developed to be smaller up to 1 μm or lower, which causes growing demand for thinness even in electrode layers.

Herein, even if powders of electrodes and dielectric become micronized, it is necessary to consider sintering matching characteristics between their materials.

In this case, metal (e.g., Ni) of electrodes starts to be earlier sintered than BaTiO3 mostly used as dielectric, at low temperature. After the sintering process, there is a problem in that the chip-capacitor suffers from crack therein, or the chip-capacitor is inferior in quality due to poor sintering matching, such as interlayer delamination.

Thus, when electrodes of electronic parts, as well as of a multilayer ceramic capacitor are formed, in order to make metal powder micronized and to adjust sintering contraction characteristics, it is preferred that metal powders are prepared to be shaped like a plate.

Therefore, metal powders should be formed to have various shapes depending on the usage. However, in the prior art, there is a limit to form a metal powder to be in a desired shape.

### SUMMARY OF THE INVENTION

The present invention has been proposed in order to overcome the above-described problems and it is, therefore, an object of the present invention to provide a preparing method of a metal powder, in which the metal powder is prepared to have the size and shape desired by a worker, thereby micronizing particles of the metal powder and adjusting sintering contraction characteristics of the metal powder, and a method for manufacturing inner electrodes for a multilayer ceramic capacitor using the same.

In accordance with one aspect of the present invention to achieve the object, there is provided a method for preparing metal powder including the steps of: providing a base substrate; forming a pattern layer, having a concave-convex pattern of a predetermined shape, on the base substrate; forming a metal film separated from the pattern layer by the concave-convex pattern; and separating the metal film from the pattern layer, thereby naturally patterning the metal film in the predetermined shape.

Also, the base substrate includes at least one of PET, PC, PE, and PP.

Also, the pattern layer has concaves formed to partially expose a top part of the base substrate.

Also, the pattern layer is formed by using at least one of nano-imprinting, gravure printing, screen printing, and photolithography.

Also, the metal film is separated from the pattern layer by removal of the pattern layer.

Also, the method for preparing metal powder further includes the steps of: forming a release layer between the pattern layer and the metal film; and separating the metal film from the pattern layer by removal of the release layer.

Also, the metal film is formed of at least one of Cu, Ni, Au, Ag, Pt, Pd, and Al.

Also, the predetermined shape includes any one of flake, rod, wire, and needle shapes.

In accordance with still another aspect of the present invention to achieve the object, there is provided a method for manufacturing inner electrodes of a multilayer ceramic capacitor including the steps of: providing a base substrate; forming a pattern layer, having a concave-convex pattern of a predetermined shape, on the base substrate; forming a metal film, separated by the concave-convex pattern, on the pattern layer; and separating the metal film from the pattern layer, thereby naturally forming metal powders, which are patterned to be in the predetermined shape by the separation of the metal film; mixing the metal powders of the predetermined shape with binder, thereby forming metal paste; and coating and sintering the metal paste on a ceramic green sheet.

Also, in the step of coating the metal paste, a mask is used to align the metal powders to be directional.

Also, the metal powder has a flake shape.

Also, the base substrate includes at least one of PET, PC, PE, and PP.

Also, the pattern layer has concaves formed to partially expose a top part of the base substrate.

Also, the pattern layer is formed by using at least one of nano-imprinting, gravure printing, screen printing, and photolithography.

Also, the metal film is separated from the pattern layer by removal of the pattern layer.

Also, the method for manufacturing inner electrodes of a multilayer ceramic capacitor the further includes the steps of: forming a release layer between the pattern layer and the metal film; and separating the metal film from the pattern layer by removal of the release layer.

Also, the metal powder has an average thickness of 0.01 to 0.5 μm, an average particle size of 0.5 to 20 μm, and an aspect ratio in a range from 10 to 200.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 to 3 are cross-sectional views showing methods for preparing metal powder in accordance with a first embodiment of the present invention, respectively;

FIG. 4 is a picture obtained when an electron microscope scans the metal powder actually prepared by the first embodiment of the present invention;

FIGS. 5A to 5D are plan views showing examples of various shapes of metal powders which may be prepared by the first embodiment of the present invention, respectively;

FIGS. 6A to 6B are cross-sectional views showing examples of different shapes for a pattern layer in accordance with the first embodiment of the present invention, respectively; and

FIGS. 7 to 9 are cross-sectional views for explaining methods for forming inner electrodes for a multilayer ceramic capacitor in accordance with a second embodiment of the present invention, respectively.

### DETAILED DESCRIPTION OF THE PREFERABLE EMBODIMENTS

Embodiments of a preparing method of metal powders in the present invention will be described in detail with reference to the accompanying drawings. When describing them with reference to the drawings, the same or corresponding component is represented by the same reference numeral and repeated description thereof will be omitted.

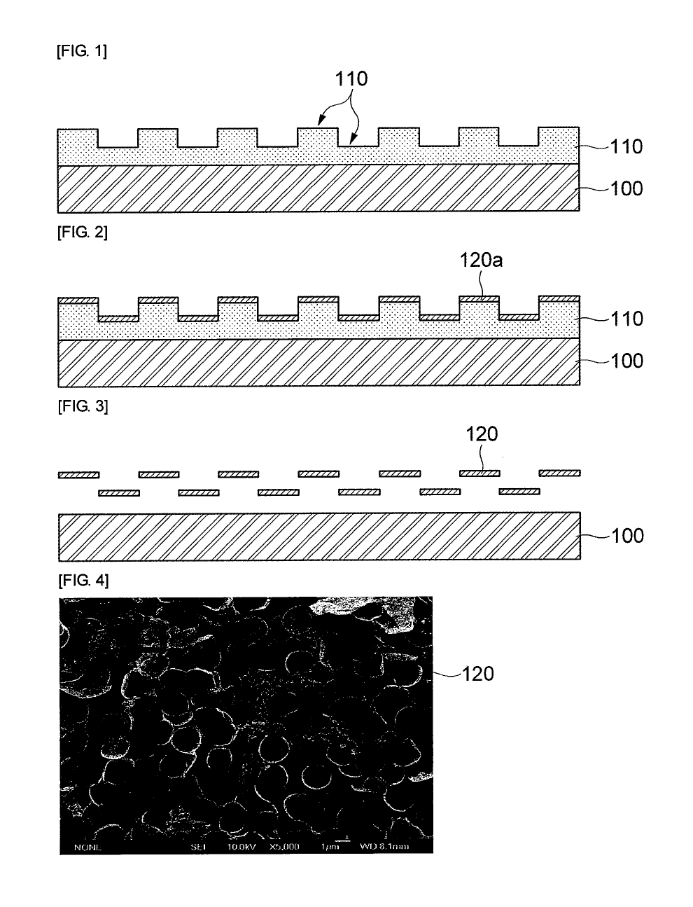

FIGS. 1 to 3 are cross-sectional views showing methods for preparing metal powder in accordance with a first embodiment of the present invention, respectively.

Referring to FIG. 1, in order to prepare metal powder in accordance with the first embodiment of the present, a base substrate 100 is provided. Herein, the base substrate 100 may be made of any material as long as it fails to be either transformed or degenerated during metal powder's processes. For example, the material of the base substrate 100 may include at least one of PET, PC, PE, and PP.

A pattern layer 110 is formed on the base substrate 100. The pattern layer 110 may have a concave-convex pattern with a predetermined shape. Herein, it is possible to prepare metal powder to be in a shape desired by a worker through change in the shape of the pattern layer 110. The pattern layer 110 may be made of a material removable through an easy method, and may be formed of thermoplastic resin, photosensitivity resin, and soluble resin. Herein, as for the thermoplastic resin, photosensitivity resin, soluble resin, and so on may be exemplified. However, the material of the pattern layer 110 is not limited by the embodiments of the present invention.

Methods for forming the pattern layer 110 may be selectively used in consideration of the material of the pattern layer 110, and the size of metal powder to be formed. Herein, the methods for forming the pattern layer 110 may include nano-imprinting, gravure printing, screen printing, photolithography, and so on.

Referring to FIG. 2, after formation of the pattern layer 110, a metal film 120a is formed on the pattern layer 110. Herein, the metal film 120a may be made of the metal powder's material desired by a worker. In this case, as for the material of the metal film 120a, Cu, Ni, Au, Ag, Pt, Pd, Al, and so on may be exemplified.

The metal film 120a may be formed according to the concave-convex pattern 111 of the pattern layer 110. In this case, the metal film 120a may be naturally separated from the pattern layer 110 by the concave-convex pattern 111.

Methods for forming the metal film 120a may include vacuum evaporation, sputtering, and so on. The method for formation of the metal film 120a is not limited by the embodiments of the present invention.

Referring to FIG. 3, after formation of the metal film 120a, the metal film 120a is separated apart from the pattern layer 110. In this case, since the metal film 120a is separated by the concave-convex pattern 111, when the metal film 120a is separated apart from the pattern layer 110, it is possible to naturally acquire metal powder 120 that has been naturally patterned to be in a pattern of pattern layer 110.

Herein, a wet method for dissolving the pattern layer 110 by solvents may be used as a method for separating the metal film 120a from the pattern layer 110. In this case, the solvents may include ethanol, toluene, acetone, xylene, and so on. However, the materials of solvents are not limited by the embodiments of the present invention. Any solvent may be used as long as it can dissolve the pattern layer 110.

After dissolving and removing the pattern layer 110, it is possible to form the metal powder 120 whose shape corresponds to the concave-convex pattern 111 of the pattern layer 110. Thereafter, some processes may be further performed including a filtering process, a purification process, a dry process, and so on. The filtering process is used to separate the metal powder 120 from the solvent, the purification process is used to increase the purity of the metal powder 120, and the dry process is used to dry the metal powder 120 from the solvent.

As for other methods for separating the metal film 120a from the pattern layer 110, there may be used a dry method in which mechanical vibration can make the metal film 120a physically separated from the pattern layer 110.

Thus, through the change in the shape of the pattern layer 110, it is possible to easily form metal powder to have a shape desired by the worker.

FIG. 4 is a picture obtained when an electron microscope scans the metal powder actually prepared by the first embodiment of the present invention.

As in FIG. 4, the metal powder may be prepared to have a thickness of 20 nm to 30 nm in a flake shape whose diameter is 2 μm.

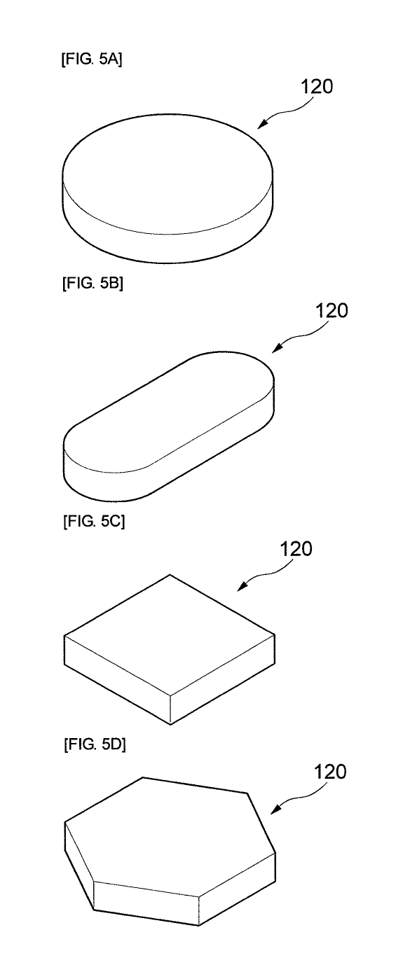

FIGS. 5A to 5D are plan views showing examples of various shapes of metal powders which may be prepared by the first embodiment of the present invention, respectively.

As in FIGS. 5A to 5D, the metal powder may have various types of cross section, which include a circular shape, an oval shape, a quadrangle shape, and a hexagon. Also, the shape of the metal powder may include at least one of flake, rod, wire, and needle shapes.

However, the shape of the metal powder is not limited by the embodiments of the present invention, and the metal powder may be formed to have various shapes depending on the pattern shape of the pattern layer.

A pattern layer for formation of the metal powder in accordance with an embodiment of the present invention may be formed to be in various shapes.

FIGS. 6A to 6B are cross-sectional views showing examples of different shapes for a pattern layer in accordance with the first embodiment of the present invention, respectively.

As in FIG. 6A, concaves 111a of the pattern layer 110 may be formed in such a manner to expose the base substrate 100.

As in FIG. 6B, a release layer 130 covering a top part of the pattern layer 110 may be further formed. In this case, the pattern layer 110 may be formed of metallic material, heat curable resin, UV curable resin, and so on. The release layer may be formed of materials which can be easily removed. As for easily removable materials, photosensitive resin, thermoplastics, and developable resin may be exemplified. In this case, the separation of the metal film 120a (indicated by reference numeral 120a of FIG. 2) from the pattern layer 110 may be achieved by dissolution and removal of the release layer 130. Thus, it is possible to reuse the pattern layer 110, thereby reducing costs taken for processes, as well as simplifying the processes. Therefore, as in the embodiments of the present invention, it is possible to use a pattern layer with a predetermined shape, thereby easily forming metal powder to be in a shape desired by the worker.

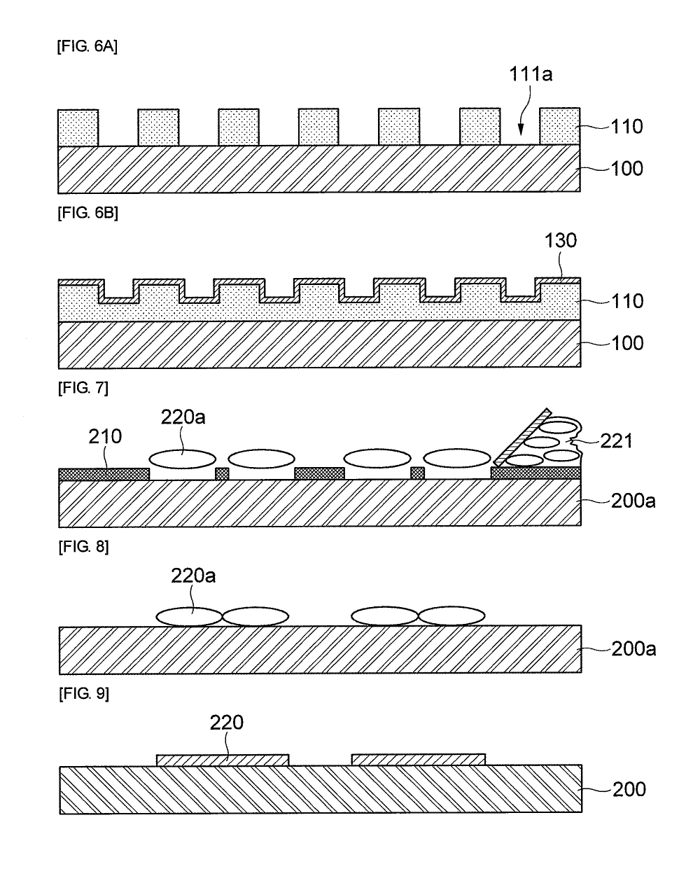

FIGS. 7 to 9 are cross-sectional views for explaining methods for forming inner electrodes for a multilayer ceramic capacitor in accordance with a second embodiment of the present invention, respectively.

For convenience, a description will be merely given of a method for forming inner electrodes of the multilayer ceramic capacitor without the overall description of a manufacturing method of the multilayer ceramic capacitor.

Also, the inner electrodes of the multilayer ceramic capacitor are formed by using the metal powder prepared through the first embodiment of the present invention. Thus, the method for forming the metal powder is as in the description of the preparing method of the metal powder in accordance with the first embodiment of the present invention.

Referring to FIG. 7, in order to form inner electrodes for a multilayer ceramic capacitor in accordance with a second embodiment of the present invention, a mask 210 with openings is aligned on a ceramic green sheet 200a, and then a metal paste 221 is coated selectively on the ceramic green sheet 200a through a squeeze.

In particular, for formation of the inner electrodes, a metal powder 220a with a predetermined shape (e.g., flake shape) may be formed. Herein, the formation of the metal powder 220a may be made by forming a metal film on the pattern layer with a predetermined shape, and then separating the metal film from the pattern layer.

Herein, the metal powder 220a may be formed to be in a flake shape, which makes it possible to prevent transverse contraction of the electrodes, and to contract the electrodes in a thickness direction. Thus, at the time of sintering the metal powder 220a, it is possible to improve connection between electrode layers therein, and to prevent dielectric layer from being defective due to electrode's agglomeration.

Herein, the metal powder 220a may have a thickness in a range from 0.01 to 0.05 μm. This is because if the metal powder 220a has a thickness of less than 0.01 μm, sintering may be performed earlier than expected. Otherwise, if the metal powder 220a has a thickness of higher than 0.05 μm, there is no use for thinness. Also, the average particle size of the metal powder 220a may range from 0.5 to 20 μm. This is because if the average particle size of the metal powder 220a is less than 0.5 μm, there is no effect in contraction control. Otherwise, if the average particle size of the metal powder 220a is higher than 20 μm, it is difficult to apply the metal powder to a print process. Also, the metal powder 220a may have an aspect ratio in a range from 10 to 200. This is because it is not easy to perform contraction control if the metal powder has an aspect ratio of less than 10, and it is difficult to apply the metal powder to the print process if the metal powder has an aspect ratio of higher than 200.

Herein, the size of the metal powder 220a is not limited by the embodiments of the present invention. If conditions of the processes are improved, it is possible to more expand the size thereof.

After the metal powder 220a is formed, the metal paste 221 is formed by mixing the formed metal powder with a binder and solvent. Herein, as for the binder, acrylic based resin, styrene based resin, cellulosic based resin, and so on may be exemplified. As for the solvent, mineral spirit, toluene, xylene, alcohol based solvents, ether based solvents, and so on may be exemplified. However, materials of the binder and types of the solvents are not limited by the embodiments of the present invention. Herein, the metal paste 221 may further include additives. As for the additives, anti-agglomeration agent, dispersant, coupling agent, and so on may be exemplified.

After the metal paste 221 is formed, the metal paste 221 is coated on the ceramic green sheet 200a with the mask 210 aligned thereon. In this case, the openings of the mask 210 may have a shape corresponding to the metal powder. Thus, as in FIG. 8, it is possible to align the metal powder in such a manner to be directional. For example, a longitudinal direction of the metal powder may be formed to coincide with a progressing direction of the inner electrodes, so that it is possible to more improve the connection of the inner electrodes.

As in FIG. 9, after the mask 210 is removed, the inner electrodes 220 may be formed on the ceramic sheet 200 by sintering the ceramic green sheet 200a and the coated metal paste 221.

Herein, it is described in connection with a specific example where the metal paste of a signal layer is formed on one ceramic green sheet 200a. However, actually, a laminate is formed by performing a sintering process after alternately laminating and compressing the ceramic green sheet and the metal paste layer in an iterative manner. Thereafter, it is possible to form a multilayer ceramic capacitor by forming external electrodes on both ends of the formed laminate.

As in embodiments of the present invention, the metal powder in a flake shape is used for the formation of inner electrodes in a multilayer ceramic capacitor, so that it is possible to implement thinness of electronic parts, and to control a sintering contraction ratio of transverse and thickness directions for the electrodes. Therefore, the present invention can improve electric conductivity and connectivity of inner electrodes, which helps to enhance reliability of the multilayer ceramic capacitor.

According to the preparing method of a metal powder in the present invention, it is possible to use a pattern to thereby prepare a metal powder depending on sizes and shapes desired by a worker.

According to the preparing method of a metal powder in the present invention, it is possible to easily prepare a metal powder to be in a flake shape beneficial to the film-type conductive layer's formation, and to adjust a sintering contraction ratio.

A preparing method of a flake-shaped metal powder proposed by the present invention can be used for formation of inner electrodes of a multilayer ceramic capacitor, so that it is possible to improve functions of the multilayer ceramic capacitor. That is, it is possible to improve electric conductivity and connectivity of inner electrodes, and thus to enhance reliability of the multilayer ceramic capacitor.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A method for preparing metal powder comprising the steps of:
providing a base substrate;
forming a pattern layer, having a concave-convex pattern of a predetermined shape, on the base substrate;
forming a metal film separated from the pattern layer by the concave-convex pattern; and
separating the metal film from the pattern layer, thereby naturally patterning the metal film in the predetermined shape.

2. The method of claim 1, wherein the base substrate includes at least one of PET, PC, PE, and PP.

3. The method of claim 1, wherein the pattern layer has concaves formed to partially expose a top part of the base substrate.

4. The method of claim 1, wherein the pattern layer is formed by using at least one of nano-imprinting, gravure printing, screen printing, and photolithography.

5. The method of claim 1, wherein the metal film is separated from the pattern layer by removal of the pattern layer.

6. The method of claim 1, further comprising the steps of:
forming a release layer between the pattern layer and the metal film; and
separating the metal film from the pattern layer by removal of the release layer.

7. The method of claim 1, wherein the metal film is formed of at least one of Cu, Ni, Au, Ag, Pt, Pd, and Al.

8. The method of claim 1, wherein the predetermined shape includes any one of flake, rod, wire, and needle shapes.

9. A method for manufacturing inner electrodes of a multilayer ceramic capacitor comprising the steps of:
providing a base substrate;
forming a pattern layer, having a concave-convex pattern of a predetermined shape, on the base substrate;
forming a metal film, separated by the concave-convex pattern, on the pattern layer; and
separating the metal film from the pattern layer, thereby naturally forming metal powders, which are patterned to be in the predetermined shape by the separation of the metal film;
mixing the metal powders of the predetermined shape with binder, thereby forming metal paste; and
coating and sintering the metal paste on a ceramic green sheet.

10. The method of claim 9, wherein, in the step of coating the metal paste, a mask is used to align the metal powders to be directional.

11. The method of claim 9, wherein the metal powder has a flake shape.

12. The method of claim 9, wherein the base substrate includes at least one of PET, PC, PE, and PP.

13. The method of claim 9, wherein the pattern layer has concaves formed to partially expose a top part of the base substrate.

14. The method of claim 9, wherein the pattern layer is formed by using at least one of nano-imprinting, gravure printing, screen printing, and photolithography.

15. The method of claim 9, wherein the metal film is separated from the pattern layer by removal of the pattern layer.

16. The method of claim 9, further comprising the steps of:
forming a release layer between the pattern layer and the metal film; and
separating the metal film from the pattern layer by removal of the release layer.

17. The method of claim 9, wherein the metal powder has an average thickness of 0.01 to 0.5 μm, an average particle size of 0.5 to 20 μm, and an aspect ratio in a range from 10 to 200.
